(19) United States
(12) Patent Application Publication
(10) Pub. No.: US 2015/0235995 A1
(43) Pub. Date: Aug. 20, 2015

(54) SEMICONDUCTOR PACKAGE AND METHOD OF FORMING THE SAME

(71) Applicants: Jin-Woo PARK, Seoul (KR); Jongho LEE, Hwaseong-si (KR)

(72) Inventors: Jin-Woo PARK, Seoul (KR); Jongho LEE, Hwaseong-si (KR)

(21) Appl. No.: 14/602,408

(22) Filed: Jan. 22, 2015

(30) Foreign Application Priority Data
Feb. 17, 2014 (KR) 10-2014-0017879

(51) Int. Cl. H01L 25/065; H01L 23/00; H01L 23/498; H01L 25/00; H01L 21/48; H01L 21/56; H01L 23/42; H01L 23/31

(52) U.S. Cl. CPC H01L 25/0657; H01L 23/42; H01L 24/17; H01L 23/3107; H01L 25/50; H01L 24/81; H01L 21/4878; H01L 21/565; H01L 23/49822; H01L 2225/06517; H01L 2225/06589; H01L 2225/06555; H01L 2224/16258; H01L 2224/8138; H01L 2225/06572

(57) ABSTRACT

A semiconductor package includes a first package substrate, a first semiconductor chip on the first package substrate, a second package substrate on the first semiconductor chip, the second package substrate including a chip region overlapping the first semiconductor chip, the chip region including a first surface defining a concave region and a second surface defining a protruding portion in sectional view, the concave region facing the first semiconductor chip, and the protruding portion facing the concave region, and a connection region adjacent to the chip region in plan view, and a second semiconductor chip on the second package substrate, wherein the chip and connection regions of the second package substrate have a same thickness.

### CROSS-REFERENCE TO RELATED APPLICATIONS

Korean Patent Application No. 10-2014-0017879, filed on Feb. 17, 2014, in the Korean Intellectual Property Office, and entitled: “Semiconductor Package and Method of Forming the Same,” is incorporated by reference herein in its entirety.

### BACKGROUND

1. Field

Example embodiments relate to a semiconductor package and a method of forming the same.

2. Description of the Related Art

High-performance, high-speed, and compact electronic systems are seeing an increasing demand, as the electronic industry matures. Various semiconductor package techniques have been proposed to meet such a demand. For example, a semiconductor package device may be configured to include a plurality of semiconductor chips mounted on a package substrate or to have a package-on-package (PoP) structure. However, there is a technical difficulty in manufacturing such conventional structures, e.g., an increase in a total thickness of the semiconductor package device.

### SUMMARY

Example embodiments provide a package-on-package (PoP) semiconductor package having a reduced pitch of connecting elements therein.

Other example embodiments provide a method of forming a PoP semiconductor package having a reduced pitch of connecting elements therein.

According to example embodiments, a semiconductor package may include a first package substrate, a first semiconductor chip on the first package substrate, a second package substrate on the first semiconductor chip, the second package substrate including a chip region overlapping the first semiconductor chip, the chip region including a first surface defining a concave region and a second surface defining a protruding portion in sectional view, the concave region facing the first semiconductor chip, and the protruding portion facing the concave region, and a connection region adjacent to the chip region in plan view, and a second semiconductor chip on the second package substrate, wherein the chip and connection regions of the second package substrate have a same thickness.

In example embodiments, the first semiconductor chip may include an upper portion inserted into the concave region.

In example embodiments, the first semiconductor chip may be electrically connected to the first package substrate via chip bumps.

In example embodiments, the semiconductor package may further include a mold layer covering a top surface of the first package substrate and at least a portion of a side surface of the first semiconductor chip and exposing the top surface of the first semiconductor chip.

In example embodiments, the mold layer may have an increasing thickness in a direction from the connection region to the first semiconductor chip.

In example embodiments, the top surface of the first semiconductor chip may be higher than that of the mold layer.

In example embodiments, the semiconductor package may further include a connecting element provided on the connection region to connect the first package substrate electrically to the second package substrate. The connecting element may have a top surface that is lower than the top surface of the first semiconductor chip.

In example embodiments, the second package substrate may include a first metal layer, a core layer, and a second metal layer that are sequentially stacked.

In example embodiments, the core layer may include a deformable polymer resin.

According to example embodiments, a method of forming a semiconductor package may include preparing a first package substrate with a first semiconductor chip, preparing a second package substrate including a first metal layer, a core layer, and a second metal layer stacked sequentially, the second package substrate having a uniform thickness and first and second surfaces facing each other, deforming the second package substrate to form a protruding portion and a concave region that are defined by the first and second surfaces, respectively, and face each other, and then combining the first package substrate to the second package substrate in such a way that the first semiconductor chip is positioned in the concave region.

In example embodiments, the first semiconductor chip may be electrically connected to the first package substrate via chip bumps.

In example embodiments, the core layer may include a deformable polymer resin.

In example embodiments, the preparing of the first package substrate may include disposing the first semiconductor chip on the first package substrate, and forming a mold layer to cover a top surface of the first package substrate and at least a portion of a side surface of the first semiconductor chip and expose the top surface of the first semiconductor chip.

In example embodiments, the top surface of the first semiconductor chip may be higher than a top surface of the mold layer.

According to example embodiments, a semiconductor package may include a first package substrate, a first semiconductor chip on the first package substrate, a second package substrate on the first semiconductor chip, the second package substrate including a concave region above the first semiconductor chip, and an upper portion of the first semiconductor chip fitting in the concave region, and a second semiconductor chip on the second package substrate, the second package substrate having a uniform thickness.

The second package substrate may include a chip region overlapping the first semiconductor chip, the chip region including the concave region, and a connection region adjacent to the chip region, the chip and connection regions of the second package substrate having a same thickness.

A distance from a top of the first package substrate to a top of the connection region of the second package substrate may be smaller than a distance from the top of the first package substrate to a top of the chip region of the second package substrate.

The concave region may overlap and surround an entire perimeter of the upper portion of the first semiconductor chip.

### BRIEF DESCRIPTION OF THE DRAWINGS

Features will become apparent to those of ordinary skill in the art by describing in detail exemplary embodiments with reference to the attached drawings, in which:

FIGS. 1 and 2 illustrate plan views of semiconductor packages according to example embodiments.

FIGS. 3 through 9 illustrate sectional views taken along line I-I′ of FIGS. 1 and 2 to illustrate examples of semiconductor packages according to example embodiments.

FIG. 10 illustrates a plan view of a semiconductor package according to other example embodiments.

FIG. 11 illustrates a sectional view taken along line II-II′ of FIG. 10 to illustrate an example of semiconductor packages according to other example embodiments.

FIG. 12 illustrates a sectional view of a semiconductor package according to still other example embodiments.

FIG. 13 illustrates a sectional view of a semiconductor package according to even other example embodiments.

FIGS. 14A through 14C illustrate sectional views of stages in exemplary methods of fabricating an upper package substrate according to example embodiments.

FIGS. 15A through 15D illustrate sectional views of stages in exemplary methods of fabricating an upper package according to example embodiments.

FIGS. 16A through 16E illustrate sectional views of stages in exemplary methods of forming a lower mold layer of a lower package according to example embodiments.

FIG. 17 illustrates a sectional view of a method of connecting a lower package to an upper package according to example embodiments.

FIG. 18 illustrates a schematic block diagram of an example of electronic systems including a semiconductor package according to example embodiments.

FIG. 19 illustrates a schematic block diagram of an example of memory systems including the semiconductor package according to the embodiments.

FIG. 20 illustrates a schematic block diagram of an example of information processing systems including the semiconductor package according to example embodiments.

### DETAILED DESCRIPTION

Example embodiments will now be described more fully with reference to the accompanying drawings. Example embodiments, however, may be embodied in many different forms and should not be construed as being limited to those set forth herein; rather, these embodiments are provided so that this disclosure will be thorough and complete, and will fully convey the concept of example embodiments to those skilled in the art. In the drawings, the thicknesses of layers and regions may be exaggerated for clarity. Like reference numerals in the drawings denote like elements throughout the specification, and thus their repeated description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

It should be noted that the figures are intended to illustrate the general characteristics of methods, structure and/or materials utilized in certain example embodiments and to supplement the written description provided below. These drawings should not be interpreted as defining or limiting the range of values or properties encompassed by example embodiments. For example, the relative dimensions, e.g., thicknesses, of layers, regions and/or structural elements may be reduced or exaggerated for clarity. The use of similar or identical reference numbers in the various drawings is intended to indicate the presence of a similar or identical element or feature.

Devices and methods of forming devices according to various embodiments described herein may be embodied in microelectronic devices, e.g., integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

Unless otherwise defined, all terms (including technical and scientific terms) used herein have the same meaning as commonly understood by one of skill in the art. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

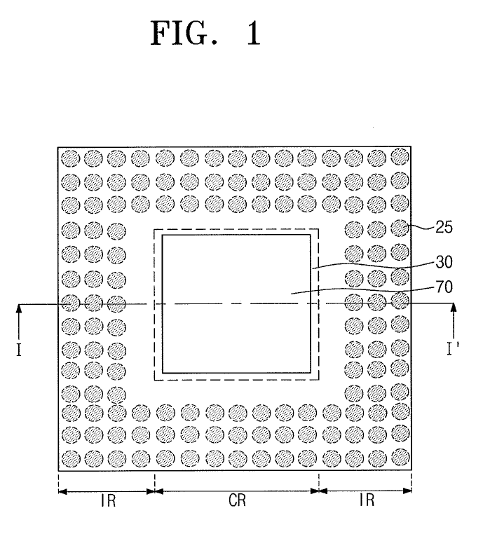

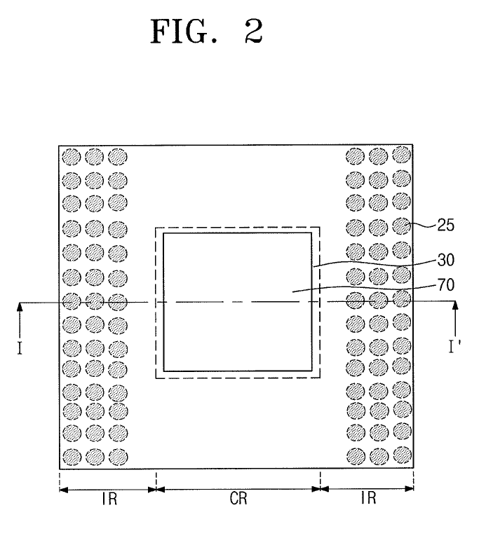

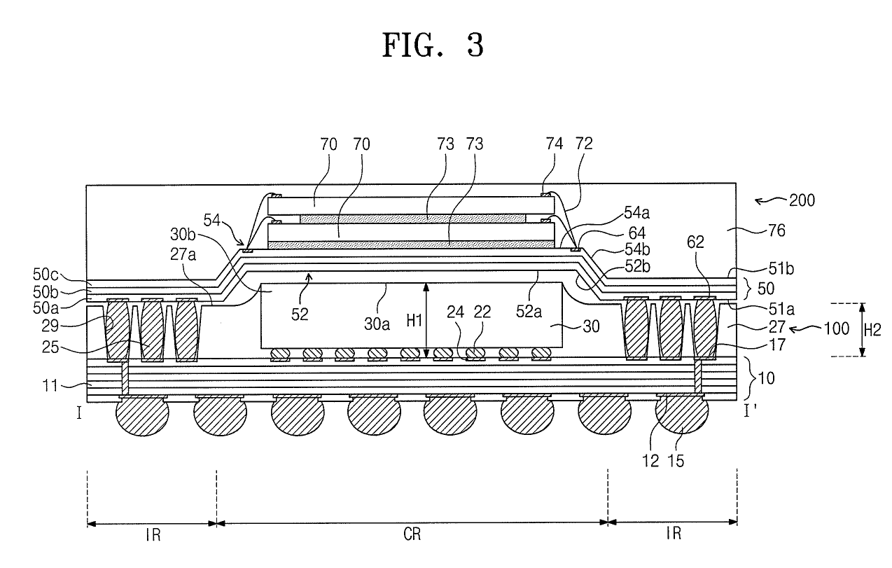

FIGS. 1 and 2 are plan views illustrating semiconductor packages according to example embodiments. FIG. 3 is a sectional view taken along line I-I′ of FIGS. 1 and 2 to illustrate an example of semiconductor packages according to example embodiments.

Referring to FIGS. 1 through 3, a semiconductor package may include a lower package 100 and an upper package 200 stacked on the lower package 100, when viewed in a section view. The semiconductor package may include a chip region CR and a connection region IR adjacent to the chip region CR, when viewed in a plan view. The chip region CR may be a central region of the semiconductor package, on which semiconductor chips are provided. The connection region IR may be an edge region of the semiconductor package.

The lower package 100 may include a lower semiconductor chip 30 disposed on a lower package substrate 10, chip bumps 22 electrically connecting the lower package substrate 10 with the lower semiconductor chip 30, and a lower mold layer 27 formed on the lower package substrate 10 to cover, e.g., surround, the lower semiconductor chip 30.

The lower package substrate 10 may be a printed circuit board (PCB) having a multi-layered structure. The lower package substrate 10 may include a plurality of insulating layers 11. Internal wires (not shown) may be disposed between the insulating layers 11. In the connection region IR, lower connection pads 17 may be provided on an edge region of a top surface of the lower package substrate 10. In the chip region CR, chip pads 24 may be provided on a central region of the top surface of the lower package substrate 10. Ball lands 12 may be provided on a bottom surface of the lower package substrate 10. External terminals 15 may be attached to the ball lands 12, respectively. The external terminals 15 may connect the semiconductor package electrically with an external device (not shown).

The lower semiconductor chip 30 may be provided on the chip pads 24. The chip bumps 22 may be attached to a bottom surface of the lower semiconductor chip 30. The chip bumps 22 may be in contact with the chip pads 24, and thus, the lower semiconductor chip 30 may be electrically connected to the lower package substrate 10. As described above, the lower semiconductor chip 30 may be mounted on the lower package substrate 10 through a flip-chip bonding process.

For example, the lower semiconductor chip 30 may be a logic device, e.g., a micro-processor chip or a memory device. In another example, the lower semiconductor chip 30 may include a portion serving as a memory device and another portion serving as a logic device.

The lower mold layer 27 may be provided on the lower package substrate 10 to fill gaps between the chip bumps 22. The lower mold layer 27 may be provided to cover most of a side surface of the lower semiconductor chip 30. A top surface 30a of the lower semiconductor chip 30 and a portion of the side surface of the lower semiconductor chip 30 may be exposed by the lower mold layer 27. The top surface 30a of the lower semiconductor chip 30 may be positioned at a higher level than a top surface 27a of the lower mold layer 27. In other words, when measured from the top surface of the lower package substrate 10, a height H1 of the top surface 30a of the lower semiconductor chip 30 may be greater than a height H2 of the top surface 27a of the lower mold layer 27. The lower semiconductor chip 30 may be protruded from, e.g., above, the lower mold layer 27. The lower mold layer 27 may have an increasing thickness in a direction from the connection region IR to the lower semiconductor chip 30. Further, the top surface 27a of the lower mold layer 27 may be concave at a position adjacent to the side surface of the lower semiconductor chip 30.

In the connection region IR, the lower mold layer 27 may be formed to have through holes 29. The through holes 29 may be formed to expose the lower connection pads 17. Bottom portions of the through holes 29 may have a width smaller than that of top portions of the through holes 29. In other words, the through holes 29 may have a downward tapered shape and a sidewall at an angle to the top surface of the lower package substrate 10.

The upper package 200 may include an upper package substrate 50, upper semiconductor chips 70 disposed on a top surface of the upper package substrate 50, bonding wires 72 electrically connecting the upper package substrate 50 with the upper semiconductor chips 70, and an upper mold layer 76 disposed on the upper package substrate 50 to cover, e.g., completely cover, the upper semiconductor chips 70.

The upper package substrate 50 may be a printed circuit board (PCB) including a first metal layer 50a, a core layer 50b, and a second metal layer 50c stacked sequentially. A silicon layer (not shown) may be further provided on a top surface of the first metal layer 50a and/or a bottom surface of the second metal layer 50c. The first and second metal layers 50a and 50c may contain copper. For example, the first and second metal layers 50a and 50c may include at least one copper pattern provided in the form of a copper clad laminate. The core layer 50b may include a deformable polymer resin. In detail, the core layer 50b may be formed of a material having properties of high elongation, high toughness, and low modulus. The core layer 50b may include, for example, poly imide or liquid crystal polymer (LCP).

The upper package substrate 50 may include the chip region CR and the connection region IR. A height of the chip region CR of the upper package substrate 50 may be higher than that of the connection region IR, when measured from the top surface of the lower package substrate 10. For example, in the chip region CR, a bottom surface 51a of the upper package substrate 50 may be upward recessed and a top surface 51b of the upper package substrate 50 may be upward protruded. In other words, the chip region CR of the upper package substrate 50 may have the bottom surface 51a defining a concave region 52 and the top surface 51b defining a protruding portion 54.

In detail, as illustrated in FIG. 3, the concave region 52 may be formed to face the first semiconductor chip 30. The concave region 52 may include a first main surface 52a facing the first semiconductor chip 30 and a first side surface 52b extending, e.g., at a slanting angle, from the first main surface 52a to the connection region IR. The protruding portion 54 may include a second main surface 54a facing the first main surface 52a and a second side surface 54b extending, e.g., at a same slanting angle as the first side surface 52b, from the second main surface 54a to the connection region IR. The concave region 52 and the protruding portion 54 may be provided to face each other. The first and second main surfaces 52a and 54a may be parallel to each other and the first and second side surfaces 52b and 54b may be parallel to each other. For example, the upper package substrate 50 may have the same thickness, e.g., as measured along a normal to the lower substrate 10, in the connection and chip regions IR and CR. The bottom surface 51a of the upper package substrate 50 may include the first main surface 52a and the first side surface 52b, and the top surface 51b of the upper package substrate 50 may include the second main surface 54a and the second side surface 54b.

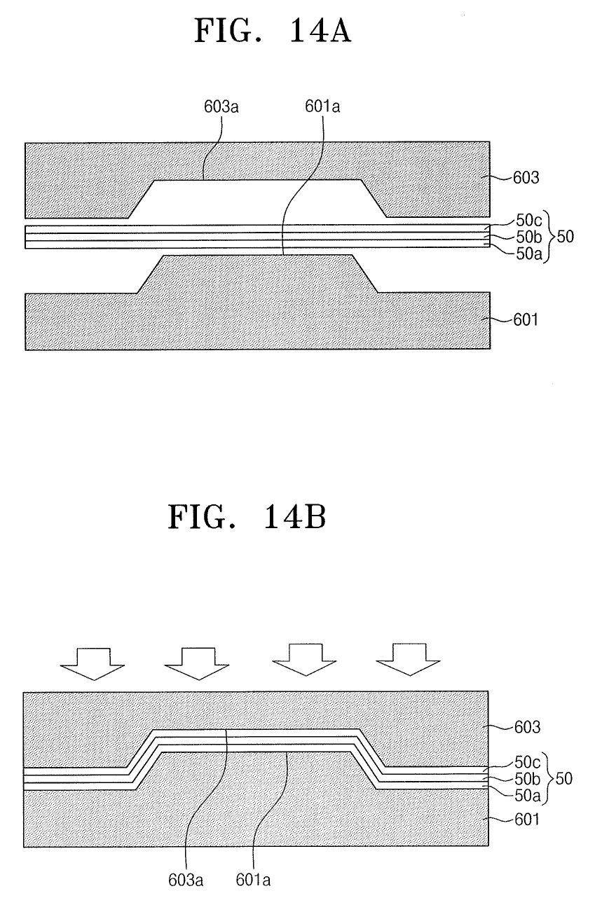

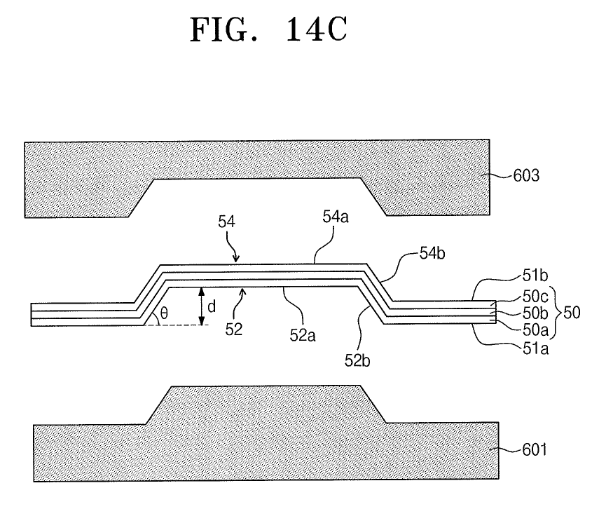

In example embodiments, as shown in FIG. 14C, a height difference d between the bottom surface 51a of the connection region IR and the first main surface 52a may be about 1 mm or less. An angle θ between an extension of the bottom surface 51a of the connection region IR (dashed line in FIG. 14C) and the first side surface 52b may range from about 0° to about 90°. The first and second side surfaces 52b and 54b may be at the same angle relative to the bottom surface 51a.

Referring back to FIG. 3, upper connection pads 62 may be provided on the bottom surface 51a of the connection region IR of the upper package substrate 50. For example, the upper connection pads 62 may be provided in the connection region IR of the upper package substrate 50 to face the lower connection pads 17. Wire pads 64 may be provided on the top surface 51b of the chip region CR of the upper package substrate 50. For example, the wire pads 64 may be provided on the second main surface 54a of the upper package substrate 50.

The upper semiconductor chips 70 may be disposed on the second main surface 54a of the chip region CR of the upper package substrate 50. The upper semiconductor chips 70 may be fixed to the upper package substrate 50 by adhesive layers 73. For example, the upper semiconductor chips 70 may be a logic device, e.g., a micro-processor chip or a memory device. In another example, the upper semiconductor chips 70 may include a portion serving as a memory device and another portion serving as a logic device. Bonding pads 74 may be provided on the upper semiconductor chips 70. The bonding pads 74 may be connected to the wire pads 64 through the bonding wire 72. Accordingly, the upper semiconductor chips 70 may be electrically connected to the upper package substrate 50. An upper mold layer 76 may be formed to cover, e.g., completely cover, the upper package substrate 50 and the upper semiconductor chips 70.

The upper package 200 may be stacked on the lower package 100, and an upper portion 30b of the lower semiconductor chip 30 may be inserted into the concave region 52 of the upper package substrate 50. As shown, the lower semiconductor chip 30 and the lower mold layer 27 may be provided in such a way that the top surfaces 30a and 27a thereof are spaced apart from the bottom surface 51a of the upper package substrate 50. However, example embodiments may not be limited thereto. For example, unlike FIG. 3, the top surface 30a of the lower semiconductor chip 30 and the top surface 27a of the lower mold layer 27 may be in contact with the bottom surface 51a of the upper package substrate 50.

Connection members 25 may be provided in the through holes 29 to connect the lower connection pads 17 to the upper connection pads 62. The connection members 25 may be disposed in the connection region IR and between the lower and upper package substrates 10 and 50. For example, as shown in FIG. 1, when viewed in a plan view, the connection members 25 may be formed to enclose, e.g., completely surround perimeters of, the lower and upper semiconductor chips 30 and 70. In another example, as shown in FIG. 2, the connection members 25 may be provided at two opposite edge regions of the lower and upper semiconductor chips 30 and 70. The connection members 25 may connect the lower package 100 electrically with the upper package 200.

According to example embodiments, the upper package substrate 50 has the concave region 52, in which the upper portion 30b of the lower semiconductor chip 30 can be inserted. Thus, it is possible to reduce a space between the lower package 100 and the upper package 200, in a package-on-package structure. Accordingly, it is possible to reduce a total thickness of a semiconductor package. Further, it is possible to reduce a thickness of the connection member 25 in the package-on-package structure. This makes it possible to reduce a space between the connection members 25, in the package-on-package structure.

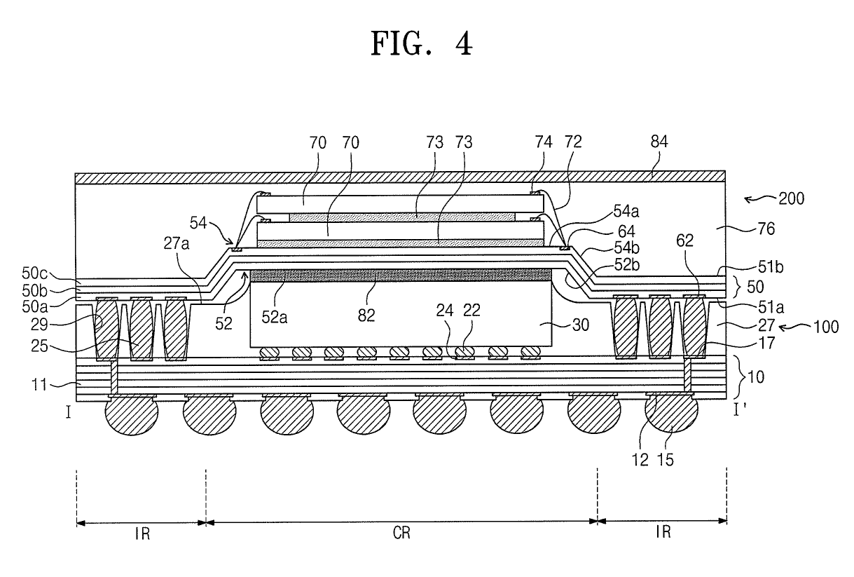

FIG. 4 is a sectional view taken along line I-I′ of FIGS. 1 and 2 to illustrate an example of semiconductor packages according to example embodiments. For the sake of brevity, the elements and features of this example that are similar to those previously shown and described with reference to FIG. 3 will not be described in much further detail.

Referring to FIG. 4, a heat-transfer layer 82 may be interposed between a portion of the lower semiconductor chip 30, which is exposed by the lower mold layer 27, and the upper package substrate 50. For example, the heat-transfer layer 82 may be provided between the top surface 30a of the lower semiconductor chip 30 and the first main surface 52a of the concave region 52 of the upper package substrate 50 facing the lower semiconductor chip 30. In certain embodiments, the heat-transfer layer 82 may include a thermal interface material (TIM).

In addition, a heat sink 84 may be additionally disposed on the upper mold layer 76. The heat sink 84 may be provided in the form of a metal plate. For example, the heat sink 84 may include at least one of copper (Cu), nickel (Ni), gold (Au), tin (Sn), or alloys thereof.

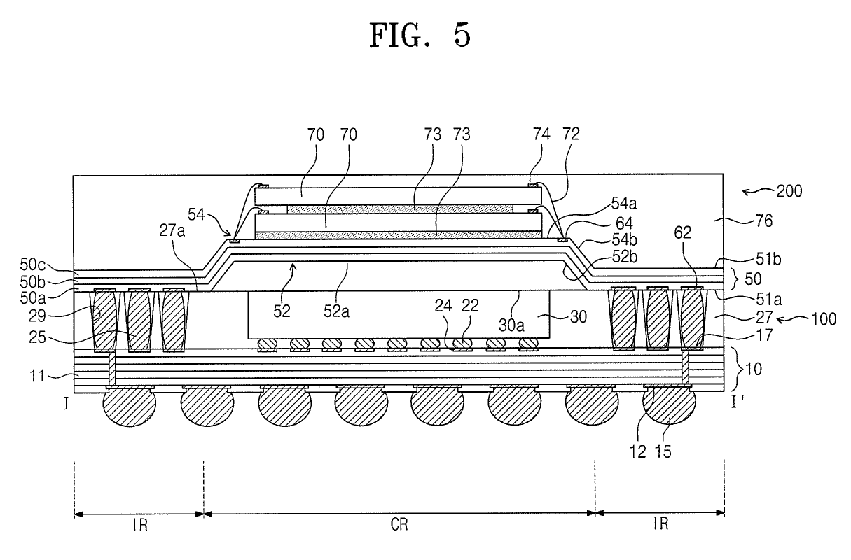

FIG. 5 is a sectional view taken along line I-I′ of FIGS. 1 and 2 to illustrate an example of semiconductor packages according to example embodiments. For the sake of brevity, the elements and features of this example that are similar to those previously shown and described with reference to FIG. 3 will not be described in much further detail.

Referring to FIG. 5, the top surface 27a of the lower mold layer 27 may be flat and may be coplanar with the top surface 30a of the lower semiconductor chip 30. As shown in FIG. 5, the top surface 27a of the lower mold layer 27 may be in contact with the top surface 30a of the lower semiconductor chip 30, but example embodiments may not be limited thereto.

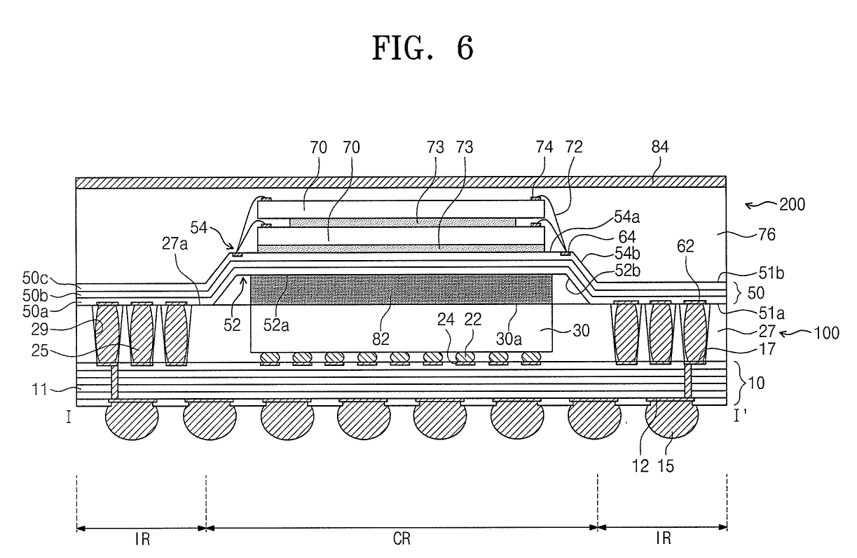

FIG. 6 is a sectional view taken along line I-I′ of FIGS. 1 and 2 to illustrate an example of semiconductor packages according to example embodiments. For the sake of brevity, the elements and features of this example that are similar to those previously shown and described with reference to FIG. 5 will not be described in much further detail.

Referring to FIG. 6, the heat-transfer layer 82 may be interposed between a portion of the lower semiconductor chip 30, which is exposed by the lower mold layer 27, and the upper package substrate 50. For example, the heat-transfer layer 82 may be provided between the top surface 30a of the lower semiconductor chip 30 and the first main surface 52a of the concave region 52 of the upper package substrate 50 facing the lower semiconductor chip 30. In certain embodiments, the heat-transfer layer 82 may include a thermal interface material (TIM).

In addition, the heat sink 84 may be additionally disposed on the upper mold layer 76. The heat sink 84 may be provided in the form of a metal plate. For example, the heat sink 84 may include at least one of copper (Cu), nickel (Ni), gold (Au), tin (Sn), or alloys thereof.

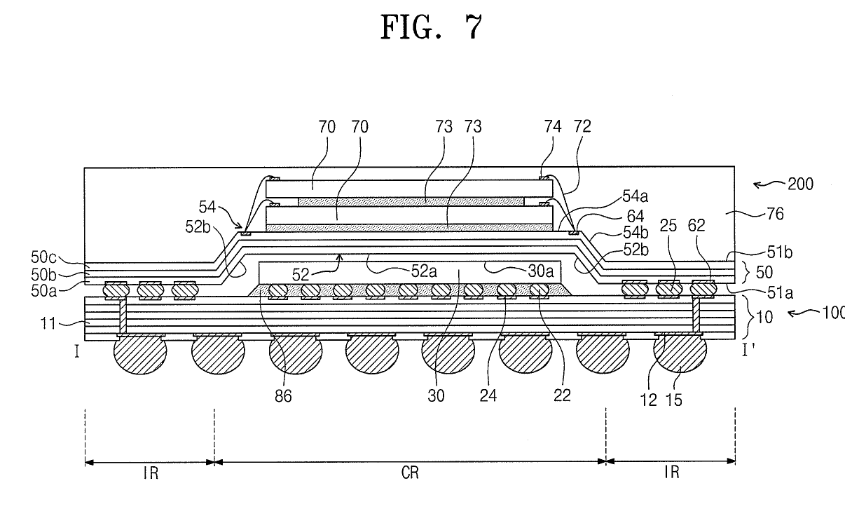

FIG. 7 is a sectional view taken along line I-I′ of FIGS. 1 and 2 to illustrate an example of semiconductor packages according to example embodiments. For the sake of brevity, the elements and features of this example that are similar to those previously shown and described with reference to FIG. 3 will not be described in much further detail.

Referring to FIG. 7, an under fill resin layer 86 may be provided between the lower package substrate 10 and the lower semiconductor chip 30 to fill a gap therebetween. The under fill resin layer 86 may fill gaps between the chip bumps 22. The under fill resin layer 86 may expose the top and side surfaces of the lower semiconductor chip 30 and the connection members 25. In the present embodiments, the lower mold layer 27 described with reference to FIG. 3 may not be formed.

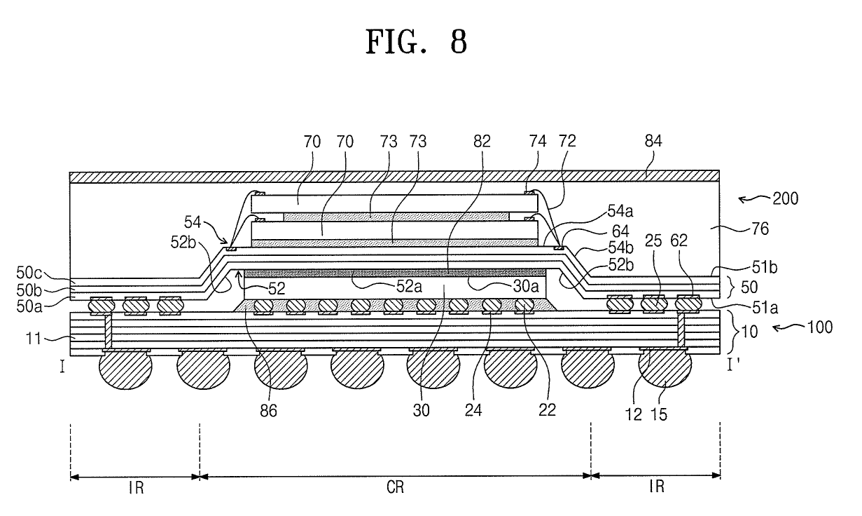

FIG. 8 is a sectional view taken along line I-I′ of FIGS. 1 and 2 to illustrate an example of semiconductor packages according to example embodiments. For the sake of brevity, the elements and features of this example that are similar to those previously shown and described with reference to FIG. 7 will not be described in much further detail.

Referring to FIG. 8, the heat-transfer layer 82 may be interposed between the lower semiconductor chip 30 and the lower package substrate 50. For example, the heat-transfer layer 82 may be provided between the top surface 30a of the lower semiconductor chip 30 and the first main surface 52a of the concave region 52 of the upper package substrate 50 facing the lower semiconductor chip 30.

In addition, the heat sink 84 may be further provided on the upper mold layer 76. The heat sink 84 may be provided in the form of a metal plate. For example, the heat sink 84 may include at least one of copper (Cu), nickel (Ni), gold (Au), tin (Sn), or alloys thereof.

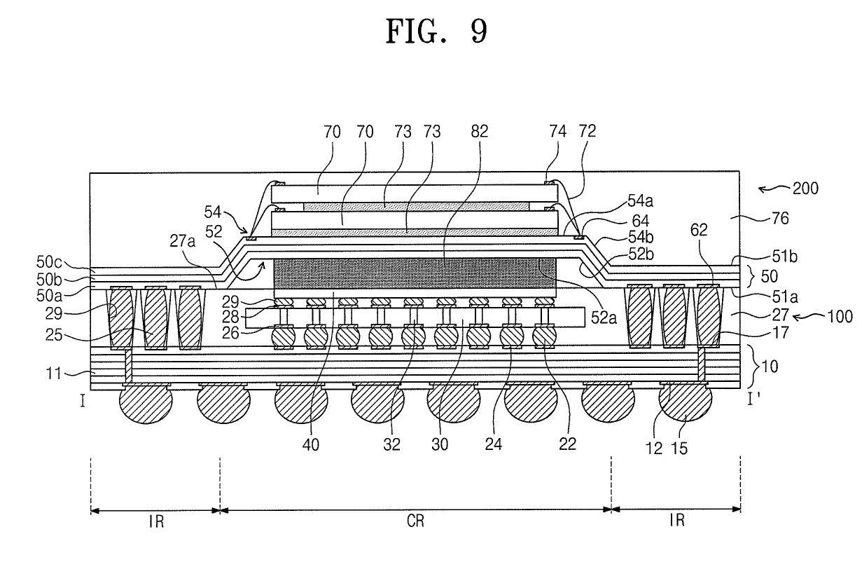

FIG. 9 is a sectional view taken along line I-I′ of FIGS. 1 and 2 to illustrate an example of semiconductor packages according to example embodiments. For the sake of brevity, the elements and features of this example that are similar to those previously shown and described with reference to FIG. 3 will not be described in much further detail.

Referring to FIG. 9, the first chip pads 24 may be provided on the top surface of the chip region CR of the lower package substrate 10. The first chip bumpers 22 may be attached to the first chip pads 24. The first lower semiconductor chip 30 may be provided on the first chip bumpers 22. Second chip pads 26 may be formed on the bottom surface of the first lower semiconductor chip 30. The second chip pads 26 may be formed of a conductive material. The first chip bumpers 22 may be provided to connect the first chip pads 24 to the second chip pads 26, respectively.

Through silicon vias (TSV) 32 may be formed to penetrate the first lower semiconductor chip 30 and may be electrically connected to the second chip pads 26. The through silicon vias 32 may not be directly connected to the second chip pads 26 and may be connected through an interconnection layer (not shown) provided in the first lower semiconductor chip 30.

The through silicon vias 32 may include at least one metal. The through silicon vias 32 may include, for example, a barrier metal layer (not shown) and an interconnection metal layer (not shown) on the barrier metal layer. The barrier metal layer may include at least one of, e.g., titanium (Ti), tantalum (Ta), titanium nitride (TiN), or tantalum nitride (TaN). The interconnection metal layer may include at least one of, e.g., aluminum (Al), gold (Au), beryllium (Ba), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), or zirconium (Zr).

A second lower semiconductor chip 40 may be stacked on the first lower semiconductor chip 30. The second lower semiconductor chip 40 may be electrically connected to the first lower semiconductor chip 30 via third chip pads 28 and second chip bumps 29. The third chip pads 28 may be provided on the top surface of the first lower semiconductor chip 30 and may be in contact with the through silicon vias 32. The second chip bumps 29 may be disposed between the third chip pads 28 and the second lower semiconductor chip 40. The third chip pads 28 and the second chip bumps 29 may include a conductive material, e.g., at least one of copper (Cu), aluminum (Al), silver (Ag), tin (Sn), or gold (Au).

The first lower semiconductor chip 30 may be a logic device. For example, the first lower semiconductor chip 30 may be a micro-processor chip or an application processor chip. The second lower semiconductor chip 40 may be a memory device.

The first lower semiconductor chip 30 and the second lower semiconductor chip 40 may be covered with the lower mold layer 27. The top surface 27a of the lower mold layer 27 may be flat and may be formed to expose a top surface 40a of the second lower semiconductor chip 40. The top surface 27a of the lower mold layer 27 may be positioned at the same level as the top surface 40a of the second lower semiconductor chip 40. The heat-transfer layer 82 may be interposed between the second lower semiconductor chip 40 and the concave region 52 of the upper package substrate 50.

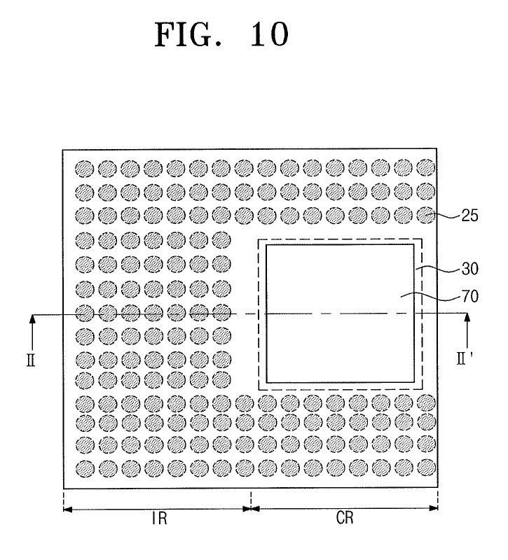

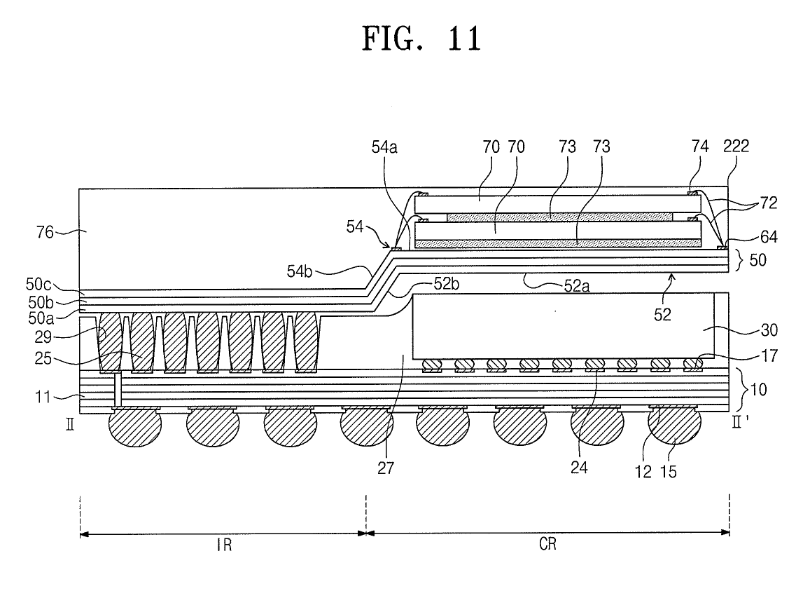

FIG. 10 is a plan view illustrating a semiconductor package according to other example embodiments, and FIG. 11 is a sectional view taken along line II-II′ of FIG. 10 to illustrate an example of semiconductor packages according to other example embodiments. For the sake of brevity, the elements and features of this example that are similar to those previously shown and described with reference to FIG. 3 will not be described in much further detail.

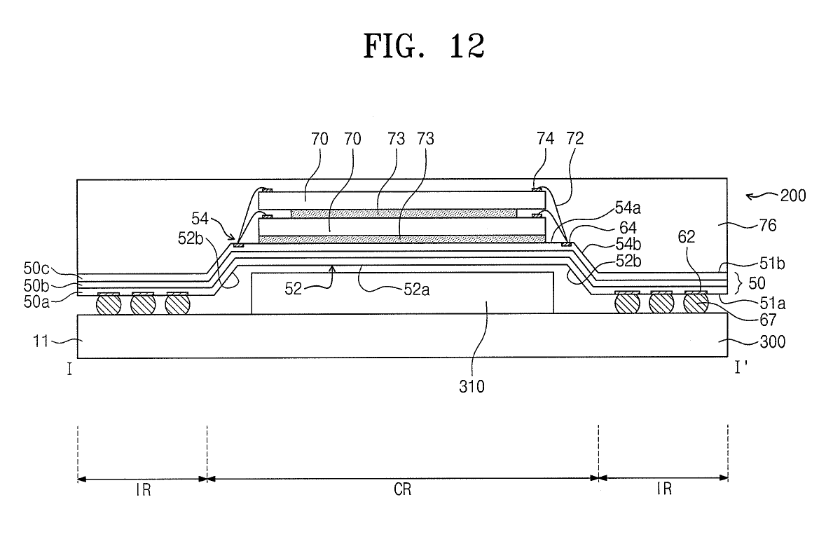

Referring to FIGS. 10 and 11, the chip region CR may be shifted from the center of the semiconductor package and may be disposed adjacent to an edge of the semiconductor package. The chip region CR of each of the previously described embodiments may be disposed to have the same arrangement as that of FIGS. 11 and 12.

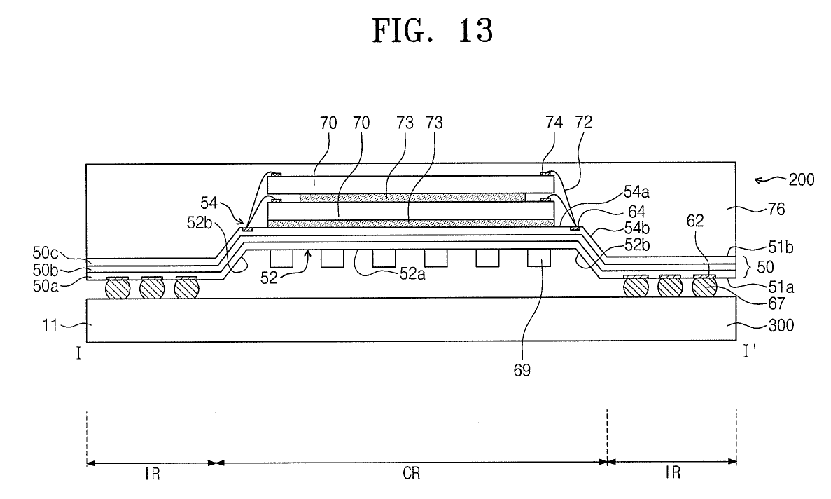

FIG. 12 is a sectional view illustrating a semiconductor package according to still other example embodiments, and FIG. 13 is a sectional view illustrating a semiconductor package according to even other example embodiments. For the sake of brevity, the elements and features of this example that are similar to those previously shown and described with reference to FIG. 3 will not be described in much further detail.

Referring to FIG. 12, the upper package 200 may be mounted on a printed circuit board 300, on which a lower package 310 is mounted. Circuit patterns (not shown), plating lead lines (not shown), and/or pads (not shown) may be provided on the printed circuit board 300. The pads may be in contact with external terminals of the lower package 310. An insulating layer may be provided on the printed circuit board 300 to cover at least partially the circuit patterns, the plating lead lines, and pads. The lower package 310 may be one of package-on-package, chip-on-package, system-on-package, and wafer-level-package structures, but example embodiments may not be limited thereto.

The connection terminals 62, which are formed on the bottom surface of the upper package substrate 50, may be connected to pads 67 on the printed circuit board 300, and thus, the upper package 200 may be directly mounted on the printed circuit board 300. The upper package 200 may be directly connected to the printed circuit board 300. The lower package 310 may be provided in such a way that at least a portion thereof is inserted into the concave region 52 of the upper package 200.

Referring to FIG. 13, a plurality of passive devices 69 may be provided on the concave region 52 of the upper package 200. For example, the passive devices 69 may be attached to the first main surface 52a of the concave region 52. The passive devices 69 may be a chip capacitor, a chip resistor, or an inductor. The chip capacitor may be a decoupling capacitor. The passive devices 69 may be configured to increase a signal processing speed of an active device or a semiconductor chip or provide a filtering function.

FIGS. 14A through 14C are sectional views illustrating an example of methods of fabricating the upper package substrate 50, according to example embodiments. For the sake of brevity, the elements and features of this example that are similar to those previously shown and described with reference to FIG. 3 will not be described in much further detail.

Referring to FIG. 14A, a first lower mold 601 and a first upper mold 603 may be prepared. The first lower mold 601 may be provided to have a protruding central portion. The first upper mold 603 may be provided to have a recessed central portion. The first lower mold 601 and the first upper mold 603 may include a protruding portion 601a and a concave region 603a, respectively, which are designed in such a way that the first lower mold 601 and the first upper mold 603 can be engaged with or separated from each other with a specific space. For example, as illustrated in FIG. 14A, the first lower mold 601 and the first upper mold 603 may have complementary shapes.

The upper package substrate 50 may be provided between the first lower mold 601 and the first upper mold 603. The upper package substrate 50 may include the first metal layer 50a, the core layer 50b, and the second metal layer 50c stacked sequentially, e.g., directly on top of each other. The core layer 50b may be formed of a material having properties of high elongation, high toughness, and low modulus. The core layer 50b may include, e.g., poly imide or liquid crystal polymer (LCP).

Referring to FIG. 14B, under the condition of high temperature, pressure is applied to the upper package substrate 50 through the first lower mold 601 and the first upper mold 603. Accordingly, the upper package substrate 50 interposed between the first lower mold 601 and the first upper mold 603 may be deformed to have a shape defined by surface profiles of the first lower mold 601 and the first upper mold 603.

Referring to FIG. 14C, the first lower mold 601 and the first upper mold 603 may be detached from the upper package substrate 50. Accordingly, the upper package substrate 50 can be formed to have the concave region 52 and the protruding portion 54.

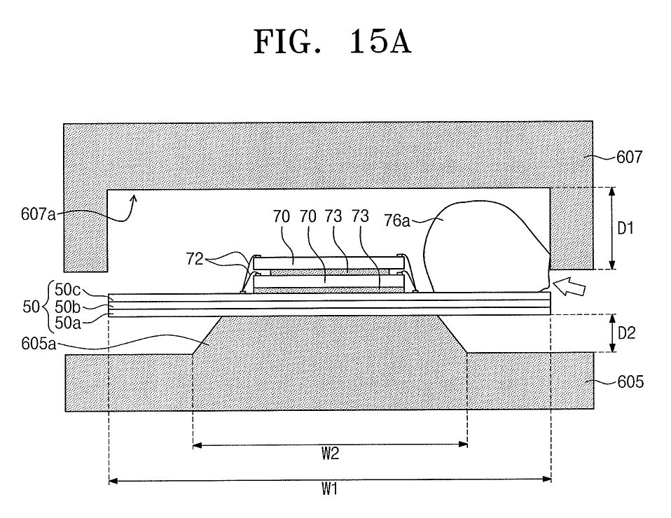

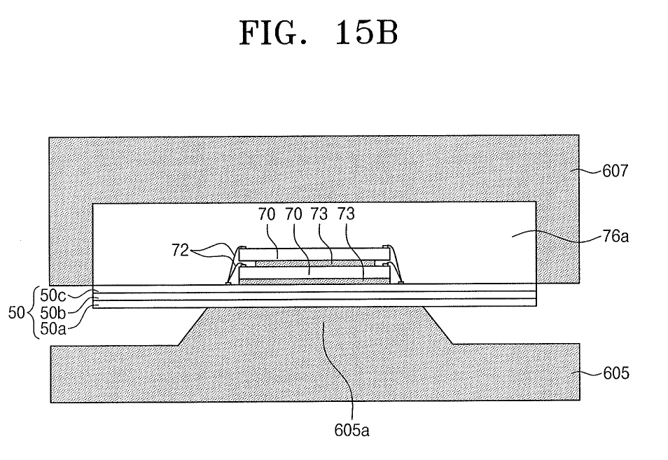

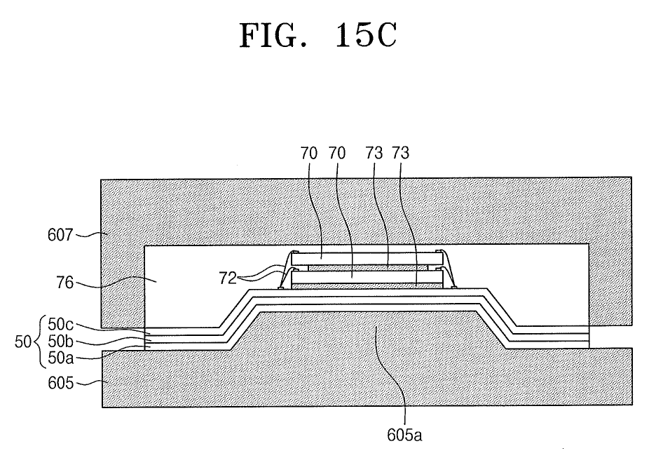

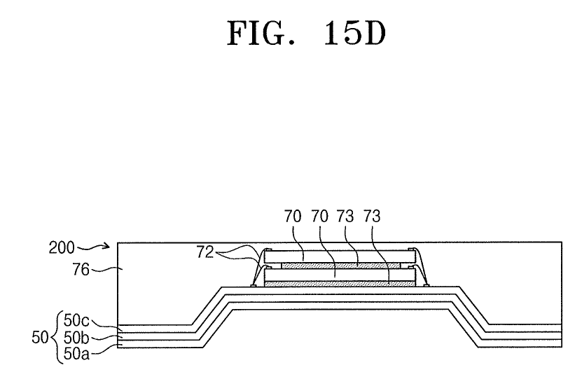

FIGS. 15A through 15D are sectional views illustrating an example of methods of fabricating the upper package 200, according to example embodiments. For the sake of brevity, the elements and features of this example that are similar to those previously shown and described with reference to FIG. 3 will not be described in much further detail.

Referring to FIG. 15A, a second lower mold 605 and a second upper mold 607 may be prepared. The second lower mold 605 may include a protruding portion 605a provided on a central region thereof The second upper mold 607 may include a concave region 607a provided on a central region thereof The protruding portion 605a of the second lower mold 605 may be formed to have a shape different from the concave region 607a of the second upper mold 607. For example, a depth D1 of the concave region 607a of the second upper mold 607 may be greater than a thickness D2 of the protruding portion of the second lower mold 605. In addition, a width W1 of the concave region 607a of the second upper mold 607 may be greater than a width W2 of the protruding portion 605a of the second lower mold 605.

The upper package 200 may be provided between the second lower mold 605 and the second upper mold 607 facing each other. For example, the upper package 200 may be provided on the second lower mold 605 and may be separated from the second upper mold 607 in a vertical direction.

The upper package 200 may include the upper package substrate 50, the upper semiconductor chips 70 provided on the top surface of the upper package substrate 50, and the bonding wires 72 connecting the upper package substrate 50 to the semiconductor chips 70.

The upper package substrate 50 may be a printed circuit board (PCB) including the first metal layer 50a, the core layer 50b, and the second metal layer 50c stacked sequentially. A silicon layer (not shown) may be further provided on a top surface of the first metal layer 50a and/or a bottom surface of the second metal layer 50c. The first and second metal layers 50a and 50c may contain copper. For example, the first and second metal layers 50a and 50c may include at least one copper pattern provided in the form of a copper clad laminate. The core layer 50b may include a deformable polymer resin. In detail, the core layer 50b may be formed of a material having properties of high elongation, high toughness, and low modulus. The core layer 50b may include, e.g., poly imide or liquid crystal polymer (LCP).

The upper semiconductor chips 70 may be fixed to the upper package substrate 50 by the adhesive layers 73. The upper semiconductor chips 70 may be a logic device, such as a micro-processor chip, or a memory device.

A molding resin 76a may be supplied to a region between the second upper mold 607 and the upper package 200.

Referring to FIGS. 15B and 15C, the second upper mold 607 may be provided to seal the upper package 200. The molding resin 76a may be provided on the upper package 200 to cover the upper semiconductor chips 70. Under the condition of high temperature, pressure may be applied to the upper package substrate 50 through the second lower mold 605 and the second upper mold 607. Accordingly, the upper package substrate 50 interposed between the second lower mold 603 and the second upper mold 607 may be deformed to have a shape defined by a surface profile of the second lower mold 605.

Referring to FIG. 15D, the second lower mold 605 and the second upper mold 607 may be detached from the upper package substrate 50 and the upper mold layer 76. Accordingly, the upper package 200 including the upper package substrate 50 and the upper mold layer 76 may be formed. In the upper package 200, the upper mold layer 76 may be provided on the upper package substrate 50, and the upper package substrate 50 may be configured to include the concave region 52 and the protruding portion 54.

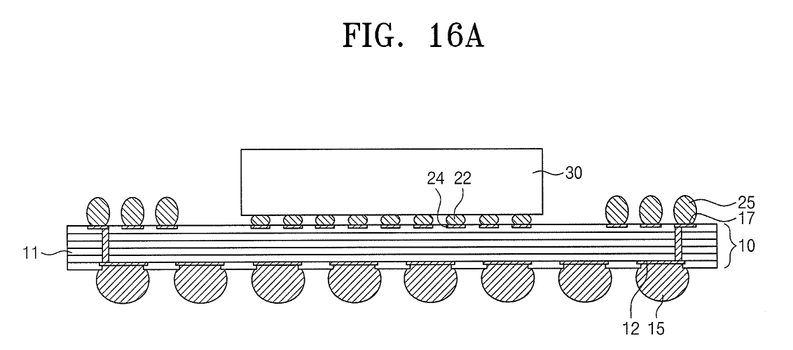

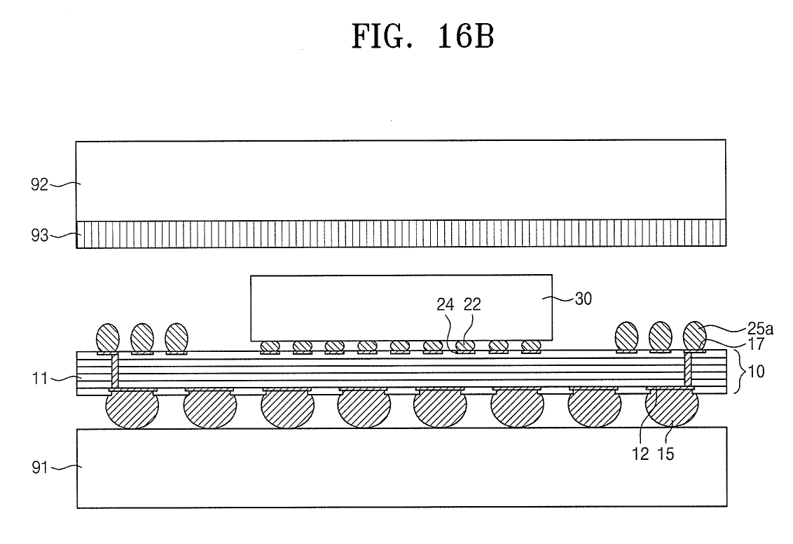

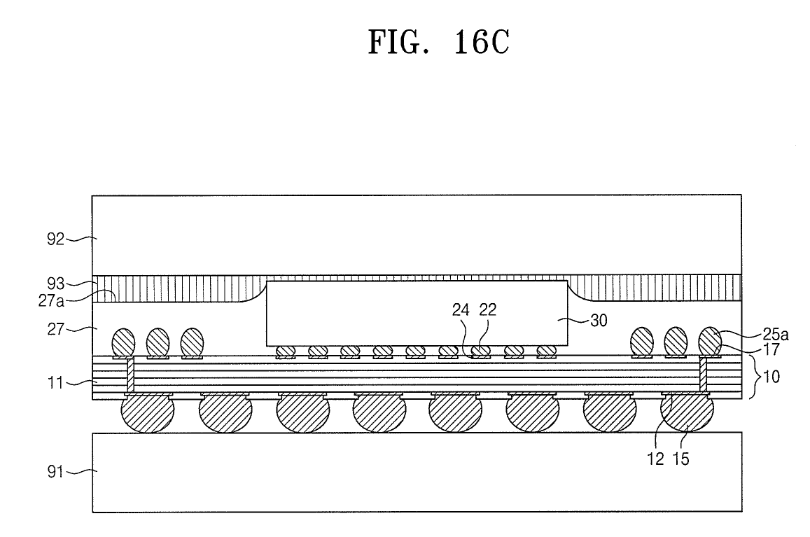

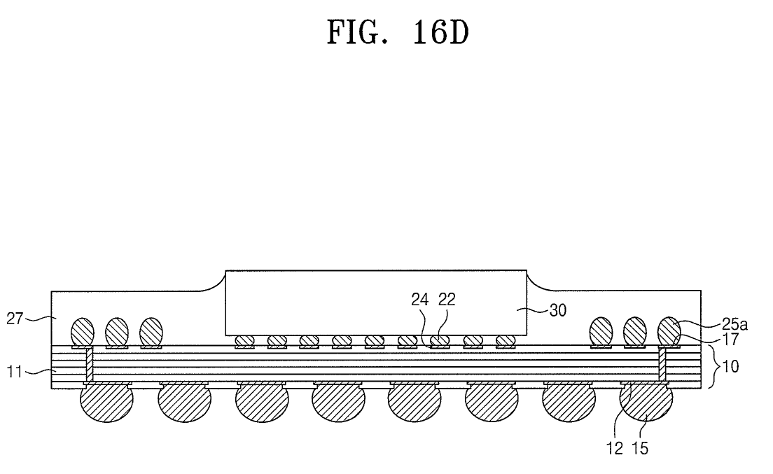

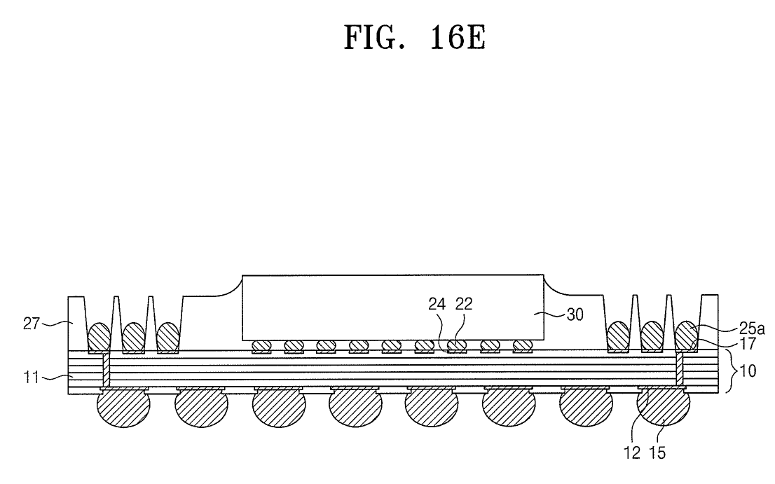

FIGS. 16A through 16D are sectional views illustrating an example of methods of forming the lower mold layer 27 of the lower package 100, according to example embodiments. For the sake of brevity, the elements and features of this example that are similar to those previously shown and described with reference to FIG. 3 will not be described in much further detail.

Referring to FIG. 16A, the lower package 100 is provided. The lower package 100 may include the lower semiconductor chip 30, the chip bumps 22, the chip pads 24, the lower connection pads 17, first preliminary connection members 25a, and the outer terminals 15, which are disposed on the lower package substrate 10.

Referring to FIG. 16B, the lower package 100 may be disposed on a lower plate 91. An upper plate 92 may be disposed on the lower package 100. The lower plate 91 and the upper plate 92 may be disposed to face each other. An elastic member 93 may be attached to a bottom surface of the upper plate 92. The elastic member 93 may be an elastomer or rubber plate.

Referring to FIGS. 16C and 16D, a molding resin may be supplied between the lower plate 91 and the upper plate 92 to cover the lower package 100. Under the condition of high temperature, pressure may be applied to the molding resin through the lower plate 91 and the upper plate 92 to form the lower mold layer 27. The top surface 27a of the lower mold layer 27 may have a shape defined by deformation of the elastic member 93. For example, the molding resin may be deformed in such a way that a distance from the lower package substrate 10 to the top surface 27a decreases in a direction oriented away from the lower semiconductor chip 30 of the lower package 100. Since the elastic member 93 is in contact with the top surface 30a of the lower semiconductor chip 30, the lower mold layer 27 may not be formed on the top surface 30a of the lower semiconductor chip 30.

Referring to FIG. 16E, the through holes 29 may be formed in the lower mold layer 27 to expose the lower connection pads 17. The through holes 29 may be formed using a laser.

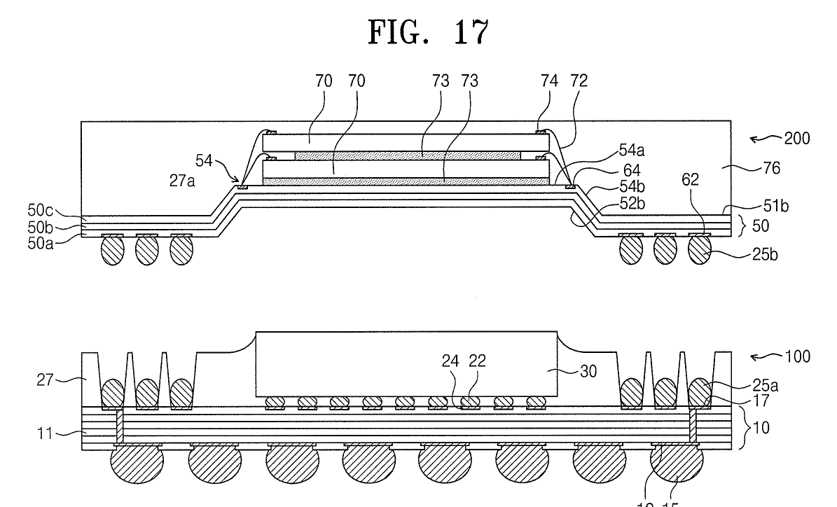

Thereafter, as shown in FIG. 17, the upper connection pads 62 and second preliminary connecting elements 25b may be formed on the bottom surface of the upper package 200 of FIG. 15D. Next, the lower package 100 of FIG. 16E and the upper package 200 may be disposed adjacent to each other to form the semiconductor package of FIG. 3.

Alternatively, the upper semiconductor chips 70 may be mounted on the upper package substrate 50 of FIG. 14C to form the upper package 200, and then, the upper package 200 may be disposed on the lower package 100 of FIG. 16E to form the semiconductor package of FIG. 3.

The previously described semiconductor package technologies may be applied to various types of a semiconductor device and a package module including the same.

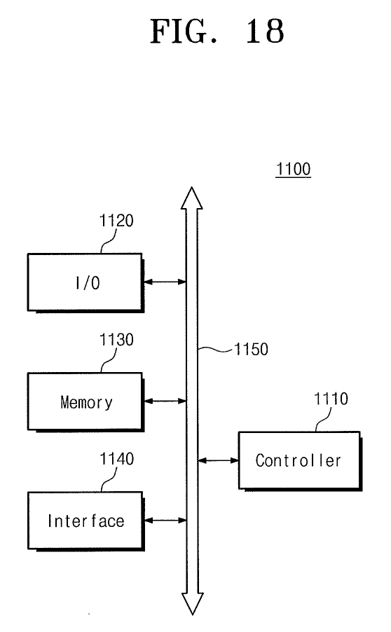

FIG. 18 is a schematic block diagram illustrating an example of electronic systems including a semiconductor package according to example embodiments. Referring to FIG. 18, an electronic system 1100 according to example embodiments may include a controller 1110, an input/output (I/O) unit 1120, a memory device 1130, an interface unit 1140 and a data bus 1150. At least two of the controller 1110, the I/O unit 1120, the memory device 1130, and the interface unit 1140 may communicate with each other via the data bus 1150. The data bus 1150 may correspond to a path through which electrical signals are transmitted. The memory device 1130 may be formed using one of the packaging techniques according to example embodiments. Further, in certain embodiments, the controller 1110 and the memory device 1130 may be integrated to form a single semiconductor package.

The controller 1110 may include at least one of, e.g., a microprocessor, a digital signal processor, a microcontroller, or another logic device with a similar function to any one thereof. The I/O unit 1120 may include, e.g., a keypad, a keyboard or a display unit. The memory device 1130 may store data and/or commands. The interface unit 1140 may transmit electrical data to a communication network or may receive electrical data from a communication network. The interface unit 1140 may be wireless or operate by cable. For example, the interface unit 1140 may include an antenna for wireless communication or a transceiver for cable communication. Although not shown in the drawing, the electronic system 1100 may further include a fast dynamic random access memory (DRAM) device and/or a fast static random access memory (SRAM) device that acts as a cache memory for improving an operation of the controller 1110.

The electronic system 1100 may be applied to, e.g., a personal digital assistant (PDA), a portable computer, a web tablet, a wireless phone, a mobile phone, a digital music player, a memory card or an electronic product. The electronic product may receive or transmit information data wirelessly.

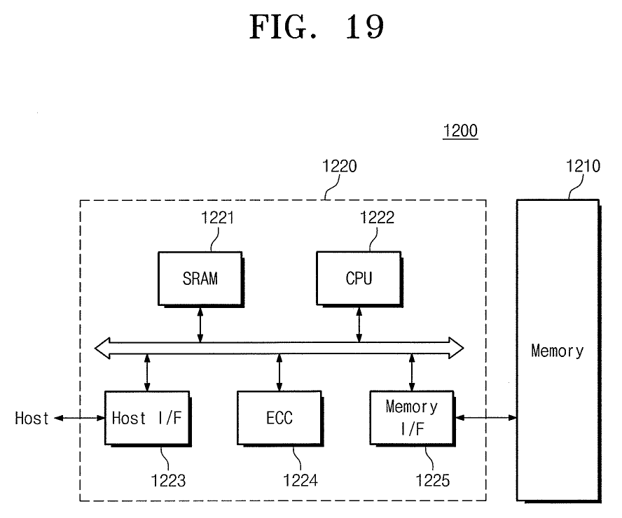

FIG. 19 is a schematic block diagram illustrating an example of memory systems including the semiconductor package according to the embodiments.

Referring to FIG. 19, a memory system 1200 according to example embodiments may include a memory device 1210. For example, the memory device 1210 may include a nonvolatile memory device and/or a SRAM device. The memory system 1200 may include a memory controller 1220 that controls data communication between a host and the memory device 1210. The memory device 1210 and/or the memory controller 1220 may be formed using one of the packaging techniques according to example embodiments.

The memory controller 1220 may include a central processing unit (CPU) 1222 that controls overall operations of the memory system 1200. In addition, the memory controller 1220 may include a SRAM device 1221 used as an operation memory of the processing unit 1222. Moreover, the memory controller 1220 may further include a host interface (I/F) unit 1223 and a memory interface (I/F) unit 1225. The host interface unit 1223 may be configured to include a data communication protocol between the memory system 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. The memory system 1200 may further include a read only memory (ROM) device that stores code data to interface with the host. The memory system 1200 may be used as a portable data storage card. Alternatively, the memory system 1200 may be provided in the form of solid state disks (SSD), instead of hard disks of computer systems.

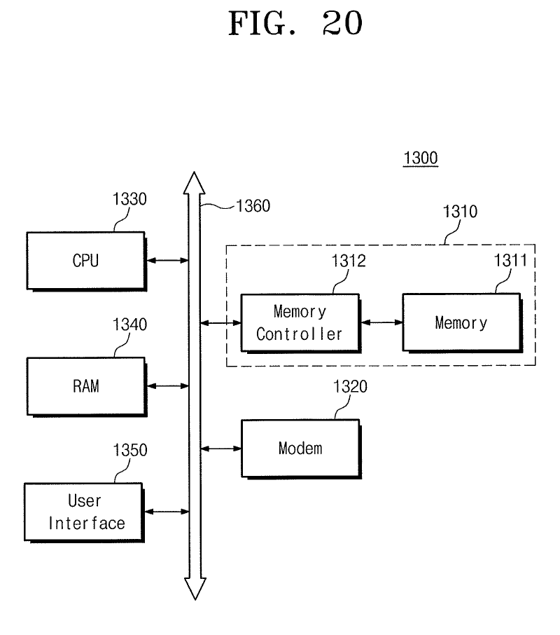

FIG. 20 is a schematic block diagram illustrating an example of information processing systems including the semiconductor package according to example embodiments.

Referring to FIG. 20, an information processing system 1300 includes a memory system 1310, which may include at least one of the semiconductor packages according to example embodiments. In certain embodiments, the information processing system 1300 may be used to realize a mobile device or a desktop computer. The information processing system 1300 also includes a modem 1320, a central processing unit (CPU) 1330, a random access memory (RAM) 1340, and a user interface 1350, which may be electrically connected to the memory system 1310 via a system bus 1360. The memory system 1310 may have the same configuration as that of the memory system 1200 described above. The memory system 1310 may include a memory 1311 and a memory controller 1312 controlling an overall operation of the memory 1311. Data processed by the CPU 1330 and/or input from the outside may be stored in the memory system 1310. Although not shown in the drawing, it will be apparent to those of ordinary skill in the art that the information processing system 1300 may be also configured to include an application chipset, a camera image processor (CIS), and/or an input/output device.

According to example embodiments, it is possible to reduce a space between packages constituting a package-on-package semiconductor package. That is, a bottom package may include a chip protruding upward from a substrate, and a shape of the top package is changed to enclose the protruding chip of the bottom package. In other words, a bottom of the top package may be concave, so a top of the chip of the bottom package may fit in the concavity of the top package. A substrate of the top package may be a flexible PCB, which can be transformed to a desired shape in a down-set manner. As such, a semiconductor package may have a reduced thickness, e.g., a volume of a solder joint connecting top and bottom packages may be reduced. Further, connecting elements in the package-on-package semiconductor package may be formed to have a fine pitch, so the number of connecting elements, e.g., the number of I/O pads, may be increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a first package substrate;
a first semiconductor chip on the first package substrate;
a second package substrate on the first semiconductor chip, the second package substrate including:
a chip region overlapping the first semiconductor chip, the chip region including a first surface defining a concave region and a second surface defining a protruding portion in sectional view, the concave region facing the first semiconductor chip, and the protruding portion facing the concave region, and
a connection region adjacent to the chip region in plan view; and a second semiconductor chip on the second package substrate, wherein the chip and connection regions of the second package substrate have a same thickness.

2. The semiconductor package as claimed in claim 1, wherein the first semiconductor chip includes an upper portion inserted into the concave region.

3. The semiconductor package as claimed in claim 1, wherein the first semiconductor chip has a top surface that is spaced apart from the second package substrate.

4. The semiconductor package as claimed in claim 3, further comprising a heat-transfer layer provided on the top surface of the first semiconductor chip and inserted into the concave region to be in contact with the second package substrate.

5. The semiconductor package as claimed in claim 1, wherein the first semiconductor chip is electrically connected to the first package substrate via chip bumps.

6. The semiconductor package as claimed in claim 1, further comprising a mold layer covering a top surface of the first package substrate and at least a portion of a side surface of the first semiconductor chip, the mold layer exposing a top surface of the first semiconductor chip.

7. The semiconductor package as claimed in claim 6, wherein the mold layer has an increasing thickness in a direction directed from the connection region to the first semiconductor chip.

8. The semiconductor package as claimed in claim 7, wherein the top surface of the first semiconductor chip is higher than that of the mold layer.

9. The semiconductor package as claimed in claim 1, further comprising a connecting element provided on the connection region to connect the first package substrate electrically to the second package substrate, the connecting element having a top surface that is lower than a top surface of the first semiconductor chip.

10. The semiconductor package as claimed in claim 1, wherein the second package substrate includes a first metal layer, a core layer, and a second metal layer that are sequentially stacked.

11. The semiconductor package as claimed in claim 10, wherein the core layer includes a deformable polymer resin.

12. A method of forming a semiconductor package, the method comprising:
preparing a first package substrate with a first semiconductor chip;
preparing a second package substrate including a first metal layer, a core layer, and a second metal layer stacked sequentially, the second package substrate having a uniform thickness and first and second surfaces facing each other;
deforming the second package substrate to form a protruding portion and a concave region that are defined by the first and second surfaces, respectively, and face each other; and
combining the first package substrate to the second package substrate, such that the first semiconductor chip is positioned in the concave region.

13. The method as claimed in claim 12, wherein preparing the first package substrate with the first semiconductor chip includes electrically connecting therebetween via chip bumps.

14. The method as claimed in claim 12, wherein preparing the second package substrate includes forming the core layer of a deformable polymer resin.

15. The method as claimed in claim 12, wherein preparing the first package substrate includes:
disposing the first semiconductor chip on the first package substrate; and
forming a mold layer to cover a top surface of the first package substrate and at least a portion of a side surface of the first semiconductor chip, such that a top surface of the first semiconductor chip is exposed.

16. The method as claimed in claim 15, wherein forming the mold layer includes having the top surface of the first semiconductor chip higher than a top surface of the mold layer.

17. A semiconductor package, comprising:
a first package substrate;
a first semiconductor chip on the first package substrate;
a second package substrate on the first semiconductor chip, the second package substrate including a concave region above the first semiconductor chip, and an upper portion of the first semiconductor chip fitting in the concave region; and
a second semiconductor chip on the second package substrate, the second package substrate having a uniform thickness.

18. The semiconductor package as claimed in claim 17, wherein the second package substrate includes:
a chip region overlapping the first semiconductor chip, the chip region including the concave region; and
a connection region adjacent to the chip region, the chip and connection regions of the second package substrate having a same thickness.

19. The semiconductor package as claimed in claim 18, wherein a distance from a top of the first package substrate to a top of the connection region of the second package substrate is smaller than a distance from the top of the first package substrate to a top of the chip region of the second package substrate.

20. The semiconductor package as claimed in claim 17, wherein the concave region overlaps and surrounds an entire perimeter of the upper portion of the first semiconductor chip.
